(19) United States
(12) Patent Application Publication
(10) Pub. No.: US 2025/0210355 A1
(43) Pub. Date: Jun. 26, 2025

(54) CHIP MANUFACTURING METHOD

(71) Applicant: DISCO CORPORATION, Tokyo (JP)

(72) Inventors: Yuki OGAWA, Tokyo (JP); Koji WATANABE, Tokyo (JP); Yusuke KON, Tokyo (JP); Kazuki HASHIMOTO, Tokyo (JP); Akihiro HIRATA, Tokyo (JP)

(21) Appl. No.: 18/968,000

(22) Filed: Dec. 4, 2024

(30) Foreign Application Priority Data
Dec. 22, 2023 (JP) 2023-216453

(51) Int. Cl. H01L 21/268; H01L 21/78

(52) U.S. Cl. CPC H01L 21/268; H01L 21/78

(57) ABSTRACT

A chip manufacturing method includes a processed groove forming step of forming a processed groove by removing a part of a film along a planned dividing line, and a dividing step of forming a plurality of chips by dividing a substrate along a bottom of the processed groove after the processed groove forming step. The processed groove forming step includes a first processed groove forming step of forming a first processed groove having a first width by applying a first laser beam along the planned dividing line, and a second processed groove forming step of forming a second processed groove having a second width different from the first width by applying a second laser beam along the planned dividing line after the first processed groove forming step.

### BACKGROUND OF THE INVENTION

### Field of the Invention

The present invention relates to a chip manufacturing method.

### Description of the Related Art

In a method of manufacturing device chips used in electronic apparatuses or the like, for example, a device such as an integrated circuit is formed in each of a plurality of regions demarcated by planned dividing lines set in a lattice manner on a top surface of a substrate (wafer). Then, a cutting apparatus or the like cuts and divides the substrate along the planned dividing lines. A plurality of device chips respectively having the devices are thereby manufactured.

Now, when a substrate provided with a film such as a low dielectric constant insulating film (Low-k film) is cut by a cutting blade, for example, the film may be peeled off from the substrate due to contact between the film and the cutting blade. When the peeling of the film reaches a device, the device is damaged.

In order to solve this problem, Japanese Patent Laid-Open No. 2005-64231, for example, proposes a technology that forms a plurality of processed grooves along the planned dividing lines by applying a laser beam along the planned dividing lines. When the cutting blade is made to cut along the formed processed grooves, the contact between the film and the cutting blade is avoided, and thus the peeling of the film from the substrate is prevented.

### SUMMARY OF THE INVENTION

However, with the technology proposed in Japanese Patent Laid-Open No. 2005-64231, a depth of end portions of a bottom of the processed groove which end portions are close to side walls may be deeper than the depth of another part of the bottom of the processed groove, and consequently the groove having a part of a sectional shape as of a pointed fang at end portions thereof may be formed. When such a groove is formed, problems occur such as a decrease in the transverse rupture strength of the chips and the occurrence of a crack in the chips.

It is accordingly an object of the present invention to provide a chip manufacturing method that can prevent the formation of a part having a shape as of a fang at end portions of the bottom of a processed groove when the processed groove is formed by applying a laser beam along a planned dividing line of a substrate having a top surface provided with a film.

In accordance with an aspect of the present invention, there is provided a chip manufacturing method for manufacturing a plurality of chips by dividing a substrate having a top surface provided with a film, along a planned dividing line of a predetermined width. The chip manufacturing method includes a processed groove forming step of forming a processed groove by removing a part of the film along the planned dividing line, and a dividing step of forming the plurality of chips by dividing the substrate along a bottom of the processed groove after the processed groove forming step, the processed groove forming step including a first processed groove forming step of forming a first processed groove having a first width in a direction of the width by applying a first laser beam along the planned dividing line, and a second processed groove forming step of forming a second processed groove having a second width different from the first width in the direction of the width by applying a second laser beam along the planned dividing line after the first processed groove forming step.

In one aspect of the present invention, the second width may be smaller than the first width. In this case, preferably, the second width is equal to or more than 30% and equal to or less than 80% of the first width.

In addition, in one aspect of the present invention, the second width may be larger than the first width.

Preferably, a first beam width of the first laser beam in the direction of the width at an irradiation position at which the film is irradiated with the first laser beam is different from a second beam width of the second laser beam in the direction of the width at an irradiation position at which the film or the substrate is irradiated with the second laser beam.

In the chip manufacturing method according to one aspect of the present invention, at a time of forming a processed groove in a planned dividing line of a substrate having a top surface provided with a film by applying a laser beam along the planned dividing line, a first processed groove having a first width is formed, and thereafter a second processed groove having a second width different from the first width is formed. Forming the processed groove including the first processed groove and the second processed groove different from each other in width in this manner can prevent the formation of a part having a shape as of a fang at end portions of the bottom of the processed groove.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a substrate and the like;

FIG. 2 is a sectional view of the substrate and the like;

FIG. 3 is a flowchart of a chip manufacturing method according to a present embodiment;

FIG. 4 is a perspective view of the substrate, a laser processing apparatus, and the like in a first processed groove forming step;

FIG. 5 is a top view of a film and the like in the first processed groove forming step;

FIG. 6 is a sectional view of the film and the like in the first processed groove forming step;

FIG. 7 is a top view of the film and the like in a second processed groove forming step;

FIG. 8 is a sectional view of the film and the like in the second processed groove forming step;

FIG. 9 is a perspective view of the substrate, a cutting apparatus, and the like in a dividing step;

FIG. 10 is a sectional view of the substrate, a cutting blade, and the like in the dividing step;

FIG. 11 is a sectional view of a film and the like in a comparative example; and

FIG. 12 is a sectional view of the film and the like according to the present embodiment.

### DETAILED DESCRIPTION OF THE PREFERRED EMBODIMENT

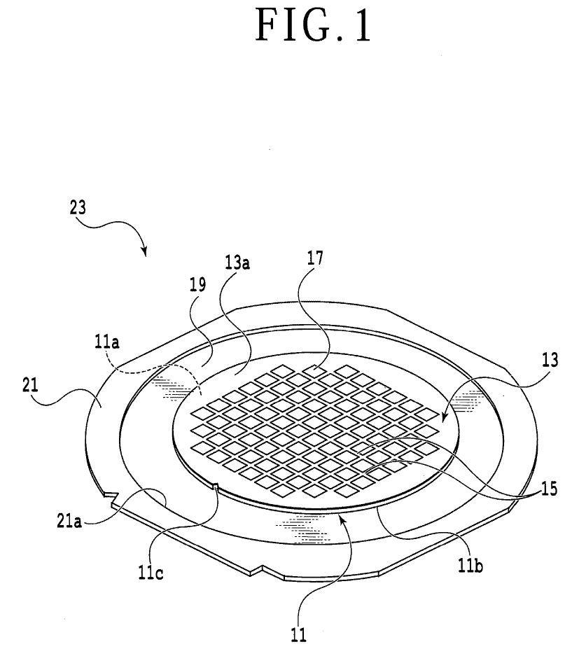

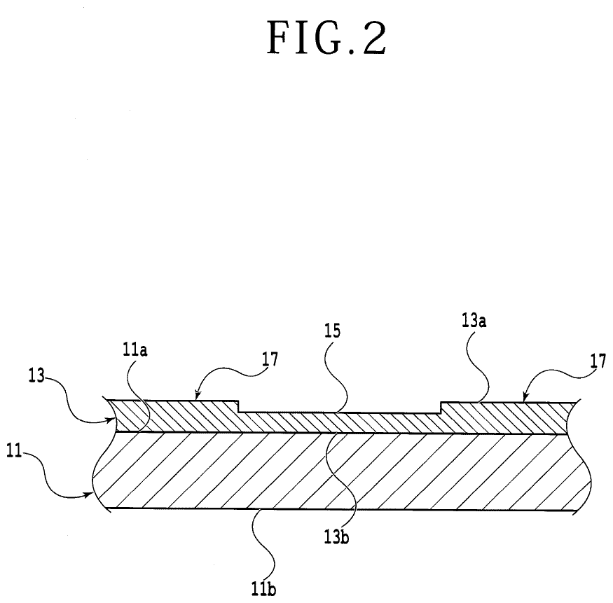

A chip manufacturing method according to an embodiment of the present invention will hereinafter be described with reference to the accompanying drawings. Description will first be made of a substrate and the like used in the chip manufacturing method according to the present embodiment. FIG. 1 is a perspective view of a substrate 11 and the like. FIG. 2 is a sectional view of the substrate 11 and the like.

As illustrated in FIG. 1, the substrate 11 is, for example, a disk-shaped wafer formed of a semiconductor material such as silicon. Specifically, the substrate 11 is formed in substantially a disk shape having a substantially circular first surface 11a and a substantially circular second surface 11b on an opposite side from the first surface 11a. A notch 11c for indicating a crystal orientation of the substrate 11 is formed in a part of an outer circumferential portion (peripheral edge portion) of the substrate 11.

A diameter of the substrate 11 (width of the first surface 11a or the second surface 11b) is, for example, equal to or more than 100 mm and equal to or less than 450 mm, or is typically 300 mm. A thickness of the substrate 11 is, for example, equal to or more than 100 μm and equal to or less than 2000 μm, or typically 775 μm. It is to be noted that the material, shape, diameter (width of the first surface 11a or the second surface 11b), and thickness of the substrate 11 are not limited to these. In addition, an orientation flat may be formed in the substrate 11 in place of the notch 11c. Further, the notch 11c or the orientation flat may not be formed in the substrate 11.

As illustrated in FIG. 2, the first surface 11a of the substrate 11 is provided with a film 13. The film 13 is formed in a film shape having a substantially circular first surface 13a having substantially the same diameter (width) as the first surface 11a and the second surface 11b of the substrate 11 and a substantially circular second surface 13b on an opposite side from the first surface 13a. That is, the shape of the film 13 is also substantially a disk shape.

The film 13, for example, includes a plurality of films such as a metallic film for wiring constituting circuits of devices 17 to be described later and a low dielectric constant insulating film (Low-k film) provided as an interlayer insulating film. A thickness of the film 13 is, for example, equal to or more than 1 μm and equal to or less than 50 μm, or typically equal to or more than 10 μm and equal to or less than 20 μm. Incidentally, the film 13 may be constituted by one film rather than the plurality of films.

The films constituting the film 13 are formed by, for example, methods such as chemical vapor deposition (CVD), thermal oxidation, and coating. However, the shape, thickness, material, and forming method of the film 13 (and the films constituting the film 13) are not limited to these, and are selected appropriately according to performance desired for the chips or the like.

As illustrated in FIG. 1 and FIG. 2, a plurality of linear planned dividing lines 15 (streets) having a predetermined width are set in a lattice manner in the first surface 13a of the film 13. The planned dividing lines 15 demarcate the first surface 13a of the film 13 into a plurality of regions. A device 17 such as an integrated circuit is provided in parts of the substrate 11 and the film 13 which parts correspond to the plurality of respective regions.

That is, the devices 17 arranged in the plurality of respective regions are each formed so as to include the substrate 11 and the film 13. Further, a plurality of chips respectively including the devices 17 are manufactured by dividing the substrate 11 and the film 13 along the planned dividing lines 15. The width of the planned dividing lines 15 is, for example, equal to or more than 10 μm and equal to or less than 500 μm, or typically equal to or more than 60 μm and equal to or less than 80 μm.

As illustrated in FIG. 1, at a time of processing the substrate 11 and the film 13, the substrate 11 is supported by an annular frame 21 via a tape 19 for the convenience of handling (transportation, holding, and the like) of the substrate 11. The frame 21 is formed of, for example, metal such as stainless steel (SUS). A central portion of the frame 21 is provided with a circular opening 21a that penetrates the frame 21 in a thickness direction. Incidentally, the diameter of the opening 21a is larger than the diameter of the substrate 11 (width of the first surface 11a or the second surface 11b).

The tape 19 in a circular shape is fixed to the substrate 11 and the frame 21. The tape 19, for example, includes a base material in a film shape and an adhesive layer (glue layer) provided on the base material. The base material is formed by resin such as polyolefin, polyvinyl chloride, or polyethylene terephthalate. The adhesive layer is formed by an epoxy-based, acryl-based, or rubber-based adhesive or the like. Incidentally, the adhesive layer may be formed by an ultraviolet curing resin that is cured by being irradiated with ultraviolet rays.

In a state in which the substrate 11 is disposed on the inside of the opening 21a of the frame 21, a central portion of the tape 19 is affixed to the second surface 11b side of the substrate 11, and an outer circumferential portion of the tape 19 is affixed to the frame 21. Thus, the substrate 11 is supported by the frame 21 via the tape 19, and a frame unit 23 is formed in which the substrate 11, the frame 21, and the tape 19 are integrated. However, the substrate 11 does not necessarily have to be supported by the frame 21.

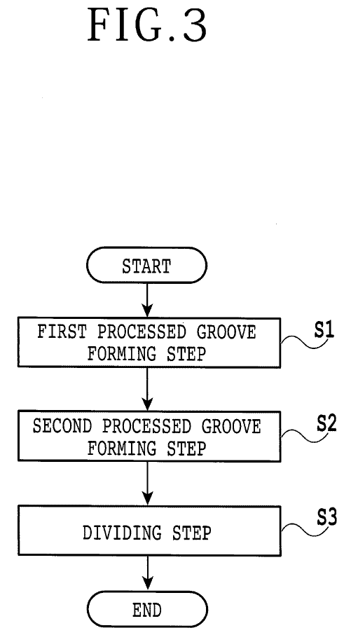

Description will next be made of a chip manufacturing method using the substrate 11 described above. FIG. 3 is a flowchart of the chip manufacturing method according to the present embodiment. As illustrated in FIG. 3, the chip manufacturing method according to the present embodiment includes a first processed groove forming step S1, a second processed groove forming step S2, and a dividing step S3.

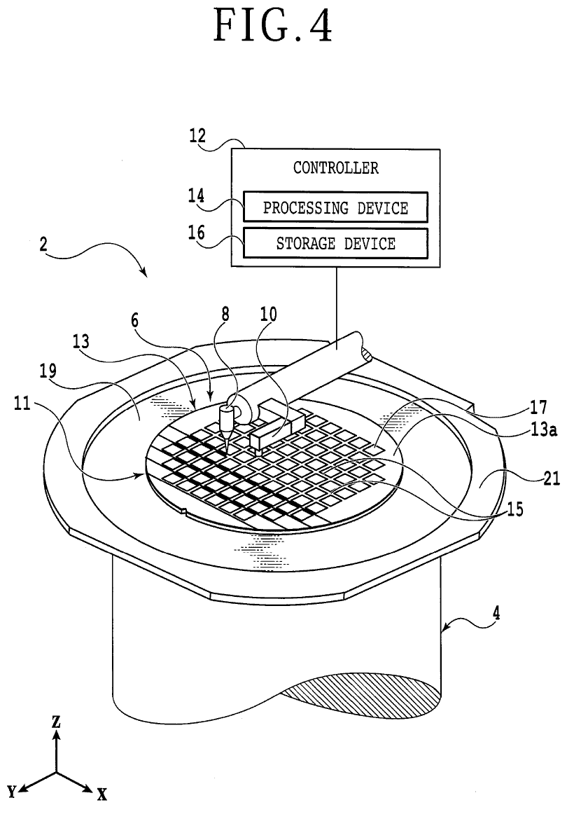

In the first processed groove forming step S1, a first processed groove is formed by irradiating the film 13 with a laser beam along the planned dividing lines 15. FIG. 4 is a perspective view of the substrate 11, a laser processing apparatus 2, and the like in the first processed groove forming step S1. Incidentally, in FIG. 4, constituent elements as a part of the laser processing apparatus 2 are represented by functional blocks.

In addition, a first direction (a direction along an X-axis or a processing feed direction), a second direction (a direction along a Y-axis or an indexing feed direction), and a third direction (a direction along a Z-axis or a vertical direction) to be used in the description of the first processed groove forming step S1 and the second processed groove forming step S2 in the following are perpendicular to one another.

As illustrated in FIG. 4, the laser processing apparatus 2 includes a holding unit 4 for holding the frame unit 23. The holding unit 4 includes a chuck table (not illustrated). The chuck table includes, for example, a disk-shaped frame body (not illustrated) formed of metal typified by SUS. A recessed portion whose upper end opens in a circular shape is formed on the upper surface side of the frame body. The recessed portion is fitted with a disk-shaped holding plate (not illustrated) that conforms to the shape of the recessed portion. Incidentally, the width (diameter) of the frame body of the chuck table is slightly smaller than the width (diameter) of the opening 21a of the frame 21.

The holding plate is formed in substantially a disk shape having a substantially circular first surface (not illustrated) and a substantially circular second surface (not illustrated) on an opposite side from the first surface. The holding plate is formed in a porous plate shape. Specifically, the holding plate is formed in a porous shape by using, for example, ceramic such as alumina (Al₂O₃) or silica (SiO₂), and has a plurality of voids connected to one another such that air can be passed between the first surface and the second surface.

The inside of the frame body is provided with a flow passage (not illustrated) having one end connected to the second surface side of the holding plate. Another end of the flow passage is connected to a suction source (not illustrated) via a pipe or the like. When the suction source is actuated in a state in which the frame unit 23 (tape 19) is set in contact with the first surface of the holding plate, a negative pressure generated from the suction source acts on the first surface via the pipe, the flow passage of the frame body, and the voids of the holding plate, and a part of the frame unit 23 is sucked by the first surface. That is, a part of the frame unit 23 is sucked and held by the chuck table of the holding unit 4.

Four clamps (not illustrated) that can fix the frame 21 constituting the frame unit 23 are provided to the periphery of the chuck table of the holding unit 4. That is, the holding unit 4 includes the four clamps. In addition, the holding unit 4 includes a rotational driving source (not illustrated) such as a motor connected to the chuck table. The chuck table of the holding unit 4 obtains a rotational driving force from the rotational driving source, and rotates about a rotational axis substantially perpendicular to the first surface of the chuck table.

In addition, the holding unit 4 is supported by a ball screw type holding unit moving mechanism (not illustrated) including a ball screw for converting a rotational driving force of a motor or the like into a linear driving force. The holding unit 4 is moved by the linear driving force of the holding unit moving mechanism along the first direction (direction along the X-axis in FIG. 4) and the second direction (direction along the Y-axis in FIG. 4) substantially parallel with the first surface of the chuck table.

The laser processing apparatus 2 includes a laser irradiating unit 6. The laser irradiating unit 6 includes a laser oscillator (not illustrated) that generates a laser beam by laser oscillation. Typically, the laser oscillator includes a laser medium such as Nd:YAG suitable for laser oscillation, and generates a pulsed laser beam having a wavelength absorbed by the film 13.

The laser irradiating unit 6 includes an irradiation head 8 that houses an optical element such as a condenser (condensing lens; not illustrated) that is provided on the downstream side of the laser oscillator along the traveling direction of the laser beam, and which condenses the laser beam. The laser beam condensed through the condenser within the irradiation head 8 is emitted from the irradiation head 8 to the first surface of the chuck table of the holding unit 4 (downward). The film 13 of the frame unit 23 held by the chuck table of the holding unit 4 is thereby irradiated with the laser beam.

A camera 10 is provided in a region adjacent to the irradiation head 8 in a direction along the X-axis. The camera 10 is configured to be able to image a region above the holding unit 4. For example, the camera 10 images a region including a part irradiated with the laser beam in the film 13 held by the holding unit 4.

The irradiation head 8 and the camera 10 are, for example, supported by a ball screw type laser irradiating unit moving mechanism (not illustrated) including a ball screw for converting the rotational driving force of a motor or the like into a linear driving force. The position in the third direction (direction along the Z-axis in FIG. 4) of the irradiation head 8 and the camera 10 can be adjusted by the laser irradiating unit moving mechanism.

The laser processing apparatus 2 includes one or a plurality of transporting mechanisms (not illustrated) that can transport the above-described frame unit 23 to the holding unit 4 or the like. The transporting mechanism(s) is (are) a robot arm, for example. The frame unit 23 is loaded onto the chuck table of the holding unit 4 by the transporting mechanism(s) such that the first surface 13a side of the film 13 is exposed. In addition, the frame unit 23 is unloaded from the chuck table to the outside of the holding unit 4 by the transporting mechanism(s).

Various constituent elements of the laser processing apparatus 2 described above are connected with a controller 12. The operation of the various constituent elements of the laser processing apparatus 2 is controlled by the controller 12. The controller 12 is, for example, constituted by a computer including a processing device 14 such as a central processing unit (CPU) and a storage device 16 including a main storage device such as a dynamic random access memory (DRAM) and/or an auxiliary memory device such as a hard disk drive and a flash memory.

The processing device 14 operates according to a program (software) stored in the storage device 16, and thereby functions of the controller 12 are implemented. However, the controller 12 may be implemented by only hardware. Incidentally, more concrete functions of the controller 12 will be described in concrete description of the following steps.

In the first processed groove forming step S1, under control of the controller 12, the laser irradiating unit 6 irradiates the film 13 with a laser beam (first laser beam) along the planned dividing lines 15. First, the frame unit 23 is held by the holding unit 4.

Specifically, the transporting mechanism(s) described above carry (carries) in the frame unit 23 from the outside of the holding unit 4, and place(s) a part of the frame unit 23 which part corresponds to the substrate 11 onto the first surface of the holding plate of the chuck table. As described above, in the present embodiment, the substrate 11 is mounted on the first surface of the holding plate of the chuck table via the tape 19 such that the first surface 13a of the film 13 is exposed upward.

When the negative pressure of the suction source is thereafter made to act on the first surface under control of the controller 12, the part of the frame unit 23 which part corresponds to the substrate 11 is sucked by the chuck table. That is, the frame unit 23 is held by the holding unit 4. Incidentally, the substrate 11 may be manually placed onto the chuck table of the holding unit 4 by an operator or the like.

Next, positional relation between the irradiation head 8 of the laser processing apparatus 2 and the frame unit 23 held by the holding unit 4 is adjusted with respect to the first direction (direction along the X-axis). Specifically, the rotational driving source rotates the holding unit 4 such that one planned dividing line 15 (first planned dividing line 15 to be processed first) among the plurality of planned dividing lines 15 provided in the first surface 13a of the film 13 is parallel with the first direction (direction along the X-axis).

In addition, the holding unit moving mechanism adjusts positions in the first direction (direction along the X-axis) and the second direction (direction along the Y-axis) of the holding unit 4 such that a part of an optical path of the laser beam (first laser beam) emitted from the irradiation head 8 coincides with an extension of the planned dividing line 15 to be processed first.

Thereafter, for example, while the laser oscillator generates a laser beam of a wavelength absorbed by the film 13, the holding unit moving mechanism moves the holding unit 4 in the first direction (direction along the X-axis). Incidentally, the position of a condensing point of the laser beam in the third direction (the position of the condensing point in a direction along the Z-axis or the height of the condensing point) is adjusted appropriately by the laser irradiating unit moving mechanism and the optical element possessed by the irradiation head 8 so as to form a first processed groove 25 of an appropriate shape.

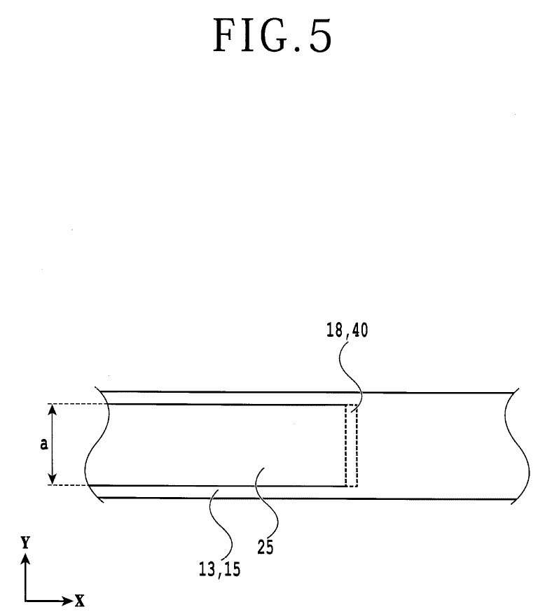

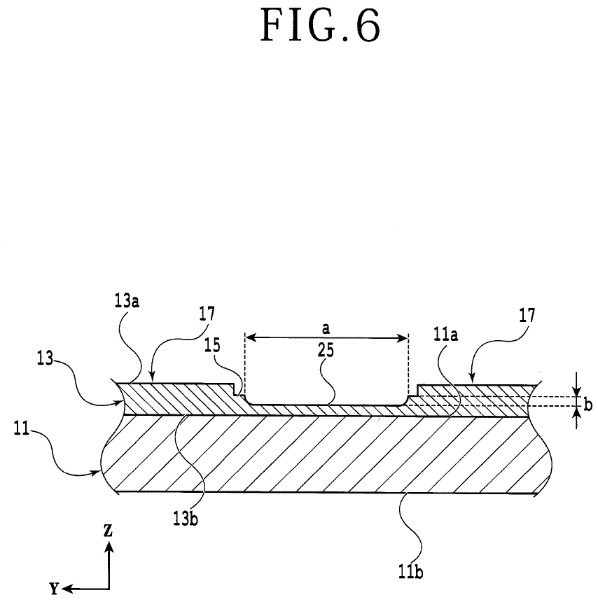

FIG. 5 is a top view of the film 13 and the like in the first processed groove forming step S1. FIG. 6 is a sectional view of the substrate 11, the film 13, and the like in the first processed groove forming step S1. As illustrated in FIG. 5, in the present embodiment, the film 13 is irradiated with a laser beam (first laser beam) 40 such that the shape of a beam spot 18 at the first surface 13a of the film 13 is a rectangular shape.

Here, the width of the laser beam 40 in the width direction of the planned dividing line 15 (first beam width or the length of a long side of the beam spot 18) at an irradiation position at which the film 13 is irradiated with the laser beam 40 is “a,” which is smaller than the width of the planned dividing line 15. This “a” is typically set so as to be smaller by 15 μm than the width of the planned dividing line 15.

In addition, the profile of the laser beam 40 (spatial distribution of intensity of the laser beam) is of a top hat type with a high uniformity of the intensity of the laser beam over a wide range as compared with a Gaussian type. Incidentally, the shape, width “a,” and intensity distribution of the beam spot 18 can be adjusted by a beam shaper, a beam expander, and the like.

As illustrated in FIG. 5 and FIG. 6, when such a laser beam 40 scans over the planned dividing line 15, a region from the first surface 13a of the film 13 to a predetermined depth is removed along the planned dividing line 15, and consequently a first processed groove 25 is formed. The magnitude of the width of the first processed groove 25 is substantially the same width (first width) a as the width of the beam spot 18.

In addition, a depth “b” of the first processed groove 25 is adjusted to be smaller than the thickness of the film 13. That is, conditions such as the intensity of the laser beam 40 are set such that the bottom of the first processed groove 25 does not reach the first surface 11a of the substrate 11.

After the laser beam 40 is applied along the first planned dividing line 15, the holding unit moving mechanism moves the holding unit 4 in a direction along the Y-axis, for example, and thereby a part of the optical path of the laser beam 40 is made to coincide with an extension of a next planned dividing line 15. When a similar operation is then repeated, the laser beam 40 is applied along the next planned dividing line 15, and thereby a similar first processed groove 25 is formed also in the next planned dividing line 15.

Further, a similar procedure is repeated also for a third and subsequent planned dividing lines 15, and thereby first processed grooves 25 are formed in all of the planned dividing lines 15 along the same direction as the first planned dividing line 15 (11 planned dividing lines 15 in total in FIG. 4).

Next, a first processed groove 25 is formed along a planned dividing line 15 intersecting the planned dividing lines 15 in which the first processed grooves 25 are formed by the above-described procedure. Specifically, the rotational driving source rotates the holding unit 4 by 90 degrees. In addition, the holding unit moving mechanism adjusts positions in the first direction (direction along the X-axis) and the second direction (direction along the Y-axis) of the holding unit 4 such that a part of the optical path of the laser beam 40 emitted from the irradiation head 8 coincides with an extension of the planned dividing line 15 to be processed next.

Then, a first processed groove 25 is formed in this planned dividing line 15 by a procedure similar to that in the case of processing the first planned dividing line 15 described above and the like. The first processed groove forming step S1 is ended when first processed grooves 25 are formed in all of the planned dividing lines 15 along a direction intersecting the first planned dividing line 15 described above (11 planned dividing lines 15 in total in FIG. 4).

Here, for example, the wavelength of the laser beam 40 is set to be equal to or more than 266 nm and equal to or less than 1064 nm or typically set at 355 nm, a repetition frequency is set to be equal to or higher than 50 kHz and equal to or lower than 5000 kHz or typically set at 1000 kHz, an average power is set to be equal to or more than 0.1 W and equal to or less than 100 W or typically set at 10 W, and the feed speed of the substrate 11 is set to be equal to or higher than 10 mm/s and equal to or lower than 1000 mm/s or typically set at 500 mm/s. However, the conditions and the like at a time of applying the laser beam 40 can be changed within a range in which the first processed grooves 25 are appropriately formed in the film 13.

Next, the second processed groove forming step S2 is performed. In the second processed groove forming step S2, second processed grooves are formed by irradiating the bottoms of the first processed grooves 25 with a laser beam (second laser beam). The operation of the laser processing apparatus 2 is similar to that in the first processed groove forming step S1.

However, the width of the beam spot of the laser beam used in the second processed groove forming step S2 and the irradiation conditions of the laser beam are different from the width “a” of the beam spot 18 of the laser beam 40 used in the first processed groove forming step S1 and the irradiation conditions of the laser beam 40. Incidentally, the height of the condensing point is adjusted appropriately by the laser irradiating unit moving mechanism and the optical element of the irradiation head 8 so as to form a second processed groove of an appropriate shape.

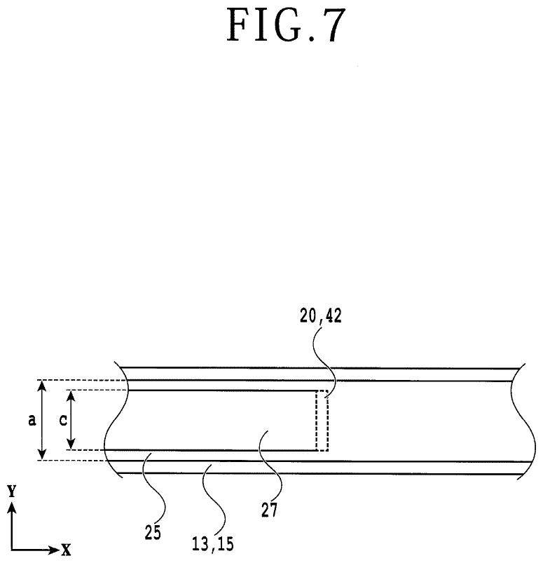

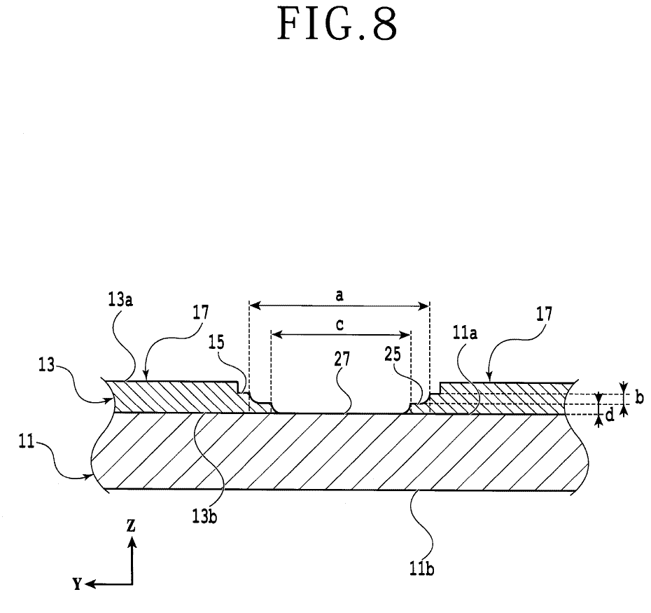

FIG. 7 is a top view of the film 13 and the like in the second processed groove forming step S2. FIG. 8 is a sectional view of the film 13 and the like in the second processed groove forming step S2. As illustrated in FIG. 7, in the present embodiment, the bottom of the first processed groove 25 is irradiated with a laser beam (second laser beam) 42 such that the shape of a beam spot 20 of the laser beam 42 at the bottom of the first processed groove 25 is a rectangular shape.

Here, the width of the laser beam 42 in the width direction of the planned dividing line 15 at the irradiation position of the film 13 (second beam width or the length of a long side of the beam spot 20) is “c,” which is smaller than the width “a” of the first processed groove 25. This “c” is specifically set at a value equal to or more than 30% and equal to or less than 80% of the width of the first processed groove 25. For example, “c” is set so as to be decreased by a range of 1 to 40 μm both inclusive with respect to the width of the first processed groove 25, or is typically set so as to be smaller by 10 μm than the width of the first processed groove 25.

In addition, the profile of the laser beam 42 is of the top hat type. Incidentally, the shape, width “c,” and intensity distribution of the beam spot 20 can be adjusted by a beam shaper, a beam expander, and the like.

As illustrated in FIG. 7 and FIG. 8, when such a laser beam 42 is scanned over the first processed groove 25, a region from the bottom of the first processed groove 25 of the film 13 to a predetermined depth is removed along the first processed groove 25, and consequently a second processed groove 27 is formed. The second processed groove forming step S2 is ended when second processed grooves 27 are formed in the bottoms of the first processed grooves 25 provided to all of the planned dividing lines 15.

Here, the magnitude of the width of the second processed groove 27 is substantially the same width (second width) “c” as the width of the beam spot 20. In addition, a depth “d” of the second processed groove 27 is typically set such that the film 13 is removed and the first surface 11a side of the substrate 11 is exposed. That is, a sum of the depth “b” of the first processed groove 25 and the depth “d” of the second processed groove 27 is set so as to be equal to or more than the thickness of the film 13. However, the first surface 11a side of the substrate 11 does not necessarily have to be exposed when the second processed groove 27 is formed.

The irradiation conditions of the laser beam 42 for forming the second processed groove 27 described above may be similar to the irradiation conditions of the laser beam 40 at the time of forming the first processed groove 25 except for the width (length of the long side) of the beam spot 20. However, the conditions and the like at the time of applying the laser beam 42 can be changed within a range in which the second processed groove 27 is appropriately formed in the bottom of the first processed groove 25.

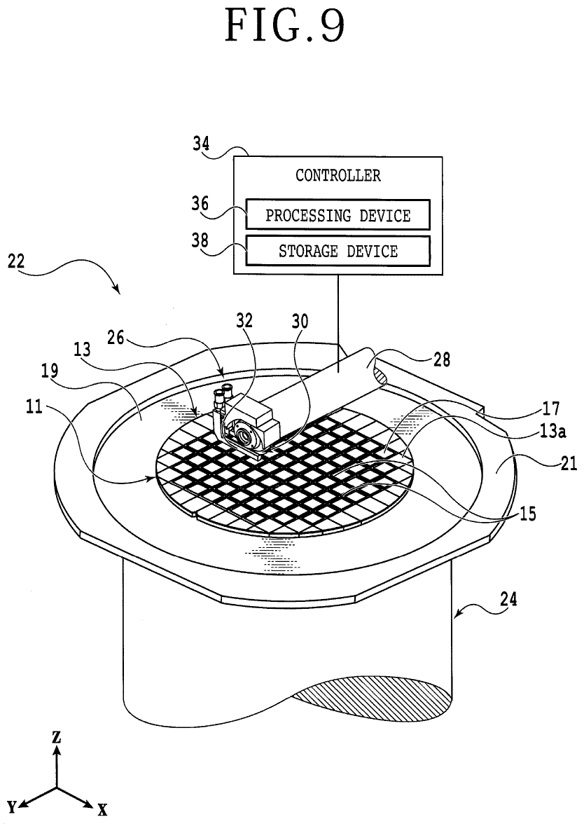

Next, the dividing step S3 is performed. FIG. 9 is a perspective view of the substrate 11, a cutting apparatus 22, and the like in the dividing step S3. Incidentally, in FIG. 9, constituent elements as a part of the cutting apparatus 22 are represented by functional blocks.

In addition, a first direction (a direction along the X-axis or a processing feed direction), a second direction (a direction along the Y-axis or an indexing feed direction), and a third direction (a direction along the Z-axis or a vertical direction) to be used in the description of the dividing step S3 in the following are perpendicular to one another. However, the directions used in the description of the dividing step S3 are independent of the directions used in the description of the first processed groove forming step S1 and the second processed groove forming step S2.

As illustrated in FIG. 9, the cutting apparatus 22 includes a holding unit 24. The holding unit 24 includes a chuck table including a holding plate and a frame body in a disk shape that have a configuration similar to that of the holding unit 4 possessed by the laser processing apparatus 2, as well as clamps. In addition, the holding unit 24 includes a rotational driving source (not illustrated) such as a motor connected to the chuck table of the holding unit 24. The chuck table of the holding unit 24 obtains a rotational driving force from the rotational driving source, and rotates about a rotational axis substantially perpendicular to the first surface of the chuck table of the holding unit 24. However, the configuration of the holding unit 24 may be different from the configuration of the holding unit 4.

The holding unit 24 is supported by a ball screw type holding unit moving mechanism (not illustrated) including a ball screw for converting a rotational driving force of a motor or the like into a linear driving force. The holding unit 24 is moved by the linear driving force of the holding unit moving mechanism along the first direction (direction along the X-axis in FIG. 9) substantially parallel with the first surface of the chuck table of the holding unit 24.

The cutting apparatus 22 includes a cutting unit 26 disposed above the holding unit 24. The cutting unit 26 includes a spindle 28 and a cutting blade 30 fitted to a distal end of the spindle 28. The spindle 28 is connected to a rotational driving source (not illustrated) such as a motor. The spindle 28 is rotated by a rotational driving force obtained from the rotational driving source. The cutting blade 30 fitted to the spindle 28 is also rotated together with the spindle 28.

The cutting blade 30 includes, for example, an annular base (not illustrated) formed by metal such as stainless steel and an annular cutting edge (not illustrated) provided to a peripheral edge portion of the annular base. The cutting edge is, for example, formed by dispersing and fixing abrasive grains formed of diamond or the like by a binding material formed of resin, metal, or the like. As this cutting edge, one having a smaller thickness than the width c of the second processed groove is used.

A pair of nozzles 32 that can supply liquid for processing (a processing liquid or a grinding liquid) typified by water to the cutting blade 30 is provided so as to sandwich the cutting blade 30 along the Y-axis. The cutting unit 26 is supported by a ball screw type cutting unit moving mechanism (not illustrated) including a ball screw for converting a rotational driving force of a motor or the like into a linear driving force. The cutting unit 26 can be moved along the second direction (direction along the Y-axis) and the third direction (direction along the Z-axis) by the cutting unit moving mechanism.

The cutting apparatus 22 includes one or a plurality of transporting mechanisms (not illustrated) that can transport the above-described frame unit 23 to the holding unit 24 or the like. The transporting mechanism(s) is (are) a robot arm, for example. The frame unit 23 is loaded onto the chuck table of the holding unit 24 by the transporting mechanism(s) such that the first surface 13a side of the film 13 is exposed. In addition, the frame unit 23 is unloaded from the chuck table of the holding unit 24 to the outside of the holding unit 24 by the transporting mechanism(s).

Various constituent elements of the cutting apparatus 22 described above are connected with a controller 34. The operation of the various constituent elements of the cutting apparatus 22 is controlled by the controller 34. As with the configuration of the controller 12 provided to the laser processing apparatus 2, the configuration of the controller 34 includes a processing device 36 and a storage device 38. However, the configuration of the controller 34 is not limited to this.

In the dividing step S3, under control of the controller 34, the cutting unit 26 divides the substrate 11 along the bottoms of the second processed grooves 27. That is, the substrate 11 is divided along the planned dividing lines 15. Specifically, first, the frame unit 23 is held by the holding unit 24.

More specifically, the transporting mechanism(s) described above load(s) the frame unit 23 onto the chuck table of the holding unit 24, and place(s) a part of the frame unit 23 which part corresponds to the substrate 11 onto the first surface of the holding plate of the chuck table of the holding unit 24. As described above, in the present embodiment, the substrate 11 is mounted on the first surface of the holding plate of the chuck table of the holding unit 24 via the tape 19 such that the first surface 13a of the film 13 is exposed upward.

When the negative pressure of the suction source is thereafter made to act on the first surface of the holding plate under control of the controller 34, the part of the frame unit 23 which part corresponds to the substrate 11 is sucked by the chuck table. That is, the frame unit 23 is held by the holding unit 24. Incidentally, the substrate 11 may be manually placed onto the chuck table of the holding unit 24 by the operator or the like.

Next, an alignment between the cutting blade 30 of the cutting unit 26 and the second processed groove 27 is performed. Specifically, for example, the rotational driving source (not illustrated) rotates the holding unit 24 such that one second processed groove 27 (first second processed groove 27 to be processed first) of the plurality of second processed grooves 27 is parallel with the first direction (direction along the X-axis).

In addition, positional relation between the holding unit 24 and the cutting unit 26 in the first direction (direction along the X-axis) and the second direction (direction along the Y-axis) is adjusted by the holding unit moving mechanism and the cutting unit moving mechanism such that the cutting blade 30 is disposed above an extension of the second processed groove 27. Further, the height of the cutting unit 26 is adjusted by the cutting unit moving mechanism such that a lower end of the cutting blade 30 is disposed a predetermined distance below the second surface 11b of the substrate 11.

Next, a processing liquid is supplied from the nozzles 32 to the cutting blade 30. Then, while the motor (not illustrated) as the rotational driving source rotates the cutting blade 30 together with the spindle 28, the holding unit moving mechanism moves the holding unit 24 along the first direction (direction along the X-axis). Thus, the cutting blade 30 and the holding unit 24 move relative to each other along the first direction (direction along the X-axis) (processing feed), and the cutting blade 30 cuts into the substrate 11 along the second processed groove 27. Then, the substrate 11 is cut at the second processed groove 27.

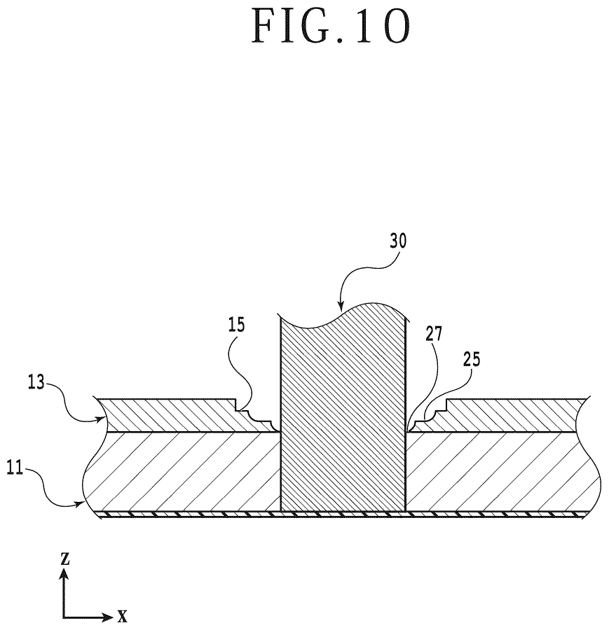

FIG. 10 is a sectional view of the substrate 11, the cutting blade 30, and the like in the dividing step S3. A processing speed (speed at which the holding unit 24 is fed in the X-axis direction) is, for example, set to be equal to or more than 5 mm/sec and equal to or less than 100 mm/sec or typically set at 50 mm/sec, and the rotational speed of the spindle 28 is, for example, set to be equal to or more than 500 rpm and equal to or less than 5000 rpm or typically set at 3000 rpm.

After the substrate 11 is cut along the one second processed groove 27, the cutting blade 30 is moved away from the first surface 13a of the film 13, for example, by the cutting unit moving mechanism by moving the cutting unit 26 in the third direction (direction along the Z-axis). In addition, by an amount of movement of the holding unit 24 along the first direction (direction along the X-axis) at the time of processing the first second processed groove 27, the holding unit moving mechanism moves the holding unit 24 in an opposite direction along the X-axis direction. When a similar operation to that in the case of the first second processed groove 27 is then repeated, the cutting blade 30 cuts into a second processed groove 27 next to the first second processed groove 27, and the substrate 11 is thereby cut similarly along the next second processed groove 27.

Further, after a second processed groove 27 is formed along the second processed groove 27 next to the first second processed groove 27, a similar procedure is repeated also for the third second processed grooves 27 and following second processed grooves 27. The substrate 11 is thereby cut at all of the second processed grooves 27 along the same direction as the first second processed groove 27 (11 second processed grooves 27 in total in FIG. 9).

Next, the substrate 11 is cut along a second processed groove 27 intersecting the first second processed groove 27 described above. Specifically, the rotational driving source rotates the holding unit 24 by 90 degrees. In addition, the positional relation between the holding unit 24 and the cutting unit 26 in the first direction (direction along the X-axis) and the second direction (direction along the Y-axis) is adjusted by the holding unit moving mechanism and the cutting unit moving mechanism such that the lower end of the cutting blade 30 is disposed above an extension of the second processed groove 27 to be cut next. Further, the height of the cutting unit 26 is adjusted by the cutting unit moving mechanism such that the lower end of the cutting blade 30 is disposed a predetermined distance below the second surface 11b of the substrate 11.

Then, the substrate 11 is cut along all of the second processed grooves 27 intersecting the first second processed groove 27 by a procedure similar to that in the case of the first second processed groove 27. Consequently, the plurality of regions demarcated by the plurality of planned dividing lines 15 are divided into individual chips.

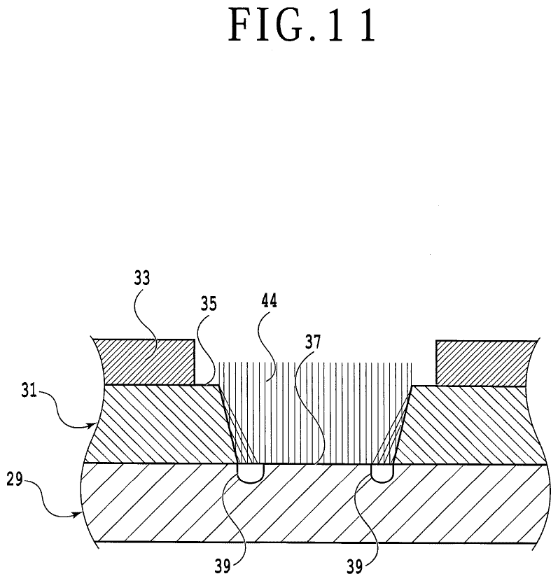

FIG. 11 is a sectional view illustrating a substrate 29, a film 31, and a laser beam 44 in a comparative example. In the comparative example illustrated in FIG. 11, the substrate 29 and the film 31 having a configuration similar to that of the substrate 11 and the film 13 according to the present embodiment are irradiated with the pulsed laser beam 44. However, in the present comparative example, the film 31 is removed by the application of the laser beam 44 so as to form a processed groove 37 having a combined depth of the depth of the first processed groove 25 and the depth of the second processed groove 27 according to the present embodiment. Therefore, one processed groove 37 is irradiated with the laser beam 44 twice or more (two passes or more).

As illustrated in FIG. 11, in the present comparative example, a part corresponding to a part of a side wall of the processed groove 37 is first formed by the laser beam 44 in a first pass applied at a time of removing the film 31. Then, the laser beam 44 in a second and subsequent passes is reflected by the part corresponding to this part of the side wall. Consequently, the pulsed laser beam 44 is considered to be applied so as to be concentrated particularly on end portions of the bottom of the processed groove 37, so that parts 39 having a sectional shape as of a fang are formed.

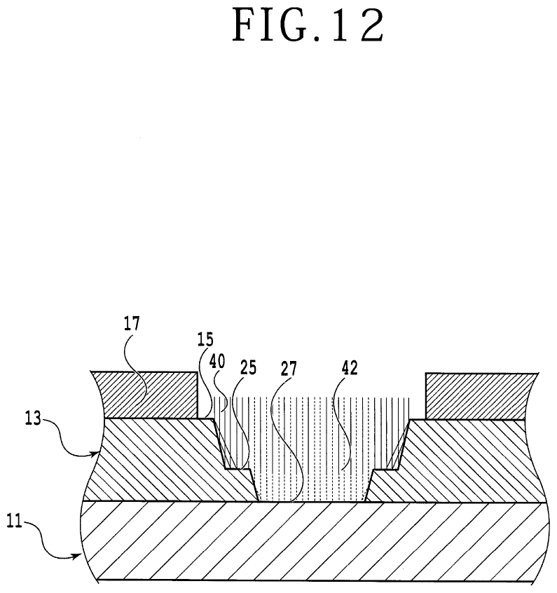

FIG. 12 is a sectional view of the substrate 11, the film 13, the first processed groove 25, and the second processed groove 27 according to the present embodiment. FIG. 12 illustrates together the laser beam 40 for forming the first processed groove 25 and the laser beam 42 for forming the second processed groove 27 for the convenience of description. In the present embodiment, as described above, the first processed groove 25 having the first width “a” is formed by applying the laser beam 40, and thereafter the second processed groove 27 having the second width “c” smaller than the first width “a” is formed by applying the laser beam 42.

Here, the width of the laser beam 42 used at the time of forming the second processed groove 27 is narrower than the width of the first processed groove 25. Hence, the laser beam 42 used at the time of forming the second processed groove 27 is not essentially reflected by the side walls of the already formed first processed groove 25. From such a principle, it is considered that in the present embodiment, the concentration of the laser beam 42 on end portions of the bottom of the second processed groove 27 (first surface 11a of the substrate 11) does not occur easily, and that parts having a sectional shape as of a fang are not easily formed at the end portions of the bottom of the second processed groove 27 (first surface 11a of the substrate 11).

When the parts 39 having a sectional shape as of a fang are formed at end portions of the bottom of a processed groove (first surface 29a of the substrate 29) as in the present comparative example, the transverse rupture strength of the chips may be decreased, and a crack may occur in the chips. However, in the present embodiment, parts having a shape as of a fang are not easily formed at end portions of the bottom of a processed groove. A decrease in the transverse rupture strength of the chips and the occurrence of a crack in the chips are consequently prevented.

Incidentally, in the above-described embodiment, the width of the beam spot 20 of the laser beam 42 in the second processed groove forming step S2 is adjusted such that the width “c” of the second processed groove 27 is smaller than the width “a” of the first processed groove 25. However, the diameter of the beam spot 20 of the laser beam 42 in the second processed groove forming step S2 may be adjusted such that the width “c” of the second processed groove 27 is larger than the width “a” of the first processed groove 25. In this case, the transverse rupture strength of the chips is considered to be increased because end portions of the first processed groove 25 are processed by the laser beam 42.

In addition, three or more processed grooves may be formed in place of the two processed grooves, that is, the first processed groove 25 and the second processed groove 27. In this case, it is preferable to form each processed groove such that the width of a processed groove formed first (processed groove formed in a shallowest region) is largest and the width is decreased as the position at which a processed groove is formed becomes deeper.

In addition, in the foregoing embodiment, the dividing step S3 divides the substrate 11 by cutting that uses the cutting apparatus 22. However, the method of dividing the substrate 11 is not limited to cutting. For example, the substrate 11 may be divided by plasma dicing that uses plasma. In addition, stealth dicing (SD, registered trademark) may be used which forms a modified region in a part of the substrate 11 by applying a laser beam of a wavelength that passes through the substrate 11, generates a crack from the modified region by applying a tensile stress to the substrate 11, and thereby divides the substrate 11.

In addition, in the second processed groove forming step S2 described above, the film 13 (bottom of the first processed groove 25) is irradiated with the laser beam 42. However, instead of the film 13, the film 13 may be removed in the first processed groove forming step S1, and a part resulting from the removal (first surface 11a of the substrate 11) may be irradiated with the laser beam 42. That is, the first surface 11a of the substrate 11 may be exposed by the application of the laser beam 40 in the first processed groove forming step S1. Also in this case, a certain degree of effect of suppressing a decrease in the transverse rupture strength of the chips and the occurrence of a crack in the chips is obtained, though not that of the foregoing embodiment.

Making description in more detail, when the film 13 is removed until the first surface 11a of the substrate 11 is exposed in the first processed groove forming step S1, parts having a sectional shape as of a fang are formed in the bottom of the first processed groove (first surface 11a of the substrate 11) as in the foregoing comparative example. When the first surface 11a of the substrate 11 is irradiated with the laser beam in the second processed groove forming step S2 that is performed next, a part from the first surface 11a of the substrate 11 to a predetermined depth is removed, and thus a second processed groove is formed. At this time, a part of the parts having the sectional shape as of a fang, which parts are formed in the first processed groove forming step, are also removed. Thus, sharp parts as the parts having the sectional shape as of a fang are reduced as compared with the comparative example. It is therefore possible to obtain an effect of suppressing a decrease in the transverse rupture strength of the chips and the occurrence of a crack in the chips.

In addition, debris (processing waste) is produced when the substrate 11 is irradiated with a laser beam. In a case where the substrate 11 is a wafer having bumps, for example, when the debris remains on the first surface 11a of the substrate 11 (particularly when debris larger than the bumps remains on the first surface 11a of the substrate 11), the debris may hinder the bonding of the bumps to electrodes, and cause a bonding failure.

As described above, when the second processed groove is formed on the substrate 11 in the second processed groove forming step S2, parts having a stepwise sectional shape are formed on the first surface 1a side of the substrate 11. Then, the debris tends to be captured by the parts having the stepwise sectional shape. Hence, the debris remaining on the first surface 11a of the substrate 11 is reduced, so that the problem of causing a bonding failure between the bumps and the electrodes as described above is less likely to occur.

Further, while the beam spot 18 of the laser beam 40 in the first processed groove forming step S1 and the beam spot 20 of the laser beam 42 in the second processed groove forming step S2 are of a rectangular shape, the beam spot 18 and the beam spot 20 may be of another shape as long as the first processed groove 25 and the second processed groove 27 having desired widths can be formed. For example, these may be of a circular shape.

Besides, structures, methods, and the like according to the foregoing embodiment and modifications thereof can be modified and implemented without departing from the objective scope of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A chip manufacturing method for manufacturing a plurality of chips by dividing a substrate having a top surface provided with a film, along a planned dividing line of a predetermined width, the chip manufacturing method comprising:
a processed groove forming step of forming a processed groove by removing a part of the film along the planned dividing line; and
a dividing step of forming the plurality of chips by dividing the substrate along a bottom of the processed groove after the processed groove forming step,
the processed groove forming step including
a first processed groove forming step of forming a first processed groove having a first width in a direction of the width by applying a first laser beam along the planned dividing line, and
a second processed groove forming step of forming a second processed groove having a second width different from the first width in the direction of the width by applying a second laser beam along the planned dividing line after the first processed groove forming step.

2. The chip manufacturing method according to claim 1, wherein
the second width is smaller than the first width.

3. The chip manufacturing method according to claim 2, wherein
the second width is equal to or more than 30% and equal to or less than 80% of the first width.

4. The chip manufacturing method according to claim 1, wherein
the second width is larger than the first width.

5. The chip manufacturing method according to claim 1, wherein
a first beam width of the first laser beam in the direction of the width at an irradiation position at which the film is irradiated with the first laser beam is different from a second beam width of the second laser beam in the direction of the width at an irradiation position at which the film or the substrate is irradiated with the second laser beam.

6. The chip manufacturing method according to claim 2, wherein
a first beam width of the first laser beam in the direction of the width at an irradiation position at which the film is irradiated with the first laser beam is different from a second beam width of the second laser beam in the direction of the width at an irradiation position at which the film or the substrate is irradiated with the second laser beam.

7. The chip manufacturing method according to claim 3, wherein
a first beam width of the first laser beam in the direction of the width at an irradiation position at which the film is irradiated with the first laser beam is different from a second beam width of the second laser beam in the direction of the width at an irradiation position at which the film or the substrate is irradiated with the second laser beam.

8. The chip manufacturing method according to claim 4, wherein
a first beam width of the first laser beam in the direction of the width at an irradiation position at which the film is irradiated with the first laser beam is different from a second beam width of the second laser beam in the direction of the width at an irradiation position at which the film or the substrate is irradiated with the second laser beam.
